(19) United States
(12) Patent Application Publication
(10) Pub. No.: US 2007/0183231 A1
(43) Pub. Date: Aug. 9, 2007

(54) Method of operating a memory system

(76) Inventors: Badrinarayanan Kothandaraman, Bangalore (IN); Binoy Jose Maliakal, Bangalore (IN); Sushma Nirmala Sambatur, Bangalore (IN)

Correspondence Address: LAW OFFICE OF DALE B. HALLING, LLC, 655 SOUTHPOINTE CT, SUITE 100, COLORADO SPRINGS, CO, 80906, US

(21) Appl. No.: 11/701,926

(22) Filed: Feb. 2, 2007

Related U.S. Application Data
(60) Provisional application No. 60/784,554, filed on Mar. 21, 2006.

(30) Foreign Application Priority Data
Feb. 2, 2006 (IN) 167/CHE/2006

(51) Int. Cl. G11C 29/00; G11C 7/00

(52) U.S. Cl. 365/200; 365/201

(57) ABSTRACT

The memory system has a current source architecture that has a separate current source for each group in a block of memory. When a leaky cell is detected, a fuse between the current source and the leaky group of cells is blown and a spare group of memory is substituted for the leaky group of memory. The current source architecture can be used in a current source test mode or in a current force test mode. The current source test mode detects if there is a leaky group of memory. In the current force test mode, the architecture determines the amount of current required by each group of memory to retain data. This information is then used to apply the required amount of current to each group of memory for data retention.

### RELATED APPLICATIONS

The present invention claims priority on provisional patent application, Ser. No. 60/784,554, filed on Mar. 21, 2006, entitled “Repair for ISB in Micro-Power SRAM Using Current Source” and is hereby incorporated by reference. The present invention also claims priority based the India patent application filed on Feb. 2, 2006.

### FIELD OF THE INVENTION

The present invention relates generally to the field of electronic memory systems and more particularly to a method of operating a memory system.

### BACKGROUND OF THE INVENTION

In micro-power SRAM (Static Random Access Memory), leaky cells can result in defective bits. In prior art systems there is no repair capability for defective (leaky) cells. These defective cells might still be functional, but fail for higher ISB (junction leakage current and sub-threshold current). A leaky cell will draw additional current during a data retention condition, which will result in other cells not receiving sufficient current to store data accurately. An example of a typical current source architecture for a SRAM is shown in FIG. 1. This figure shows the current source implementation for a single block. V_{ccx} is the power supply to the memory cells in the block (1024 rows×64 columns) that consists of 8 groups (1 group—1024 rows×8 columns). The V_{ccx} line is common for all 64 columns in a block. If any one of the cells in a groups is leaky, the V_{ccx} of that group will collapse (voltage will drop due to excess current draw) causing data retention failures. Since the V_{ccx} of each group is connected to the main V_{ccx} line through fuses, the V_{ccx} for the entire block may collapse causing data retention failure for the entire block. This leaky block will result in a higher ISB and greater data retention failures.

Thus, there exists a need for a memory current source architecture to detect and repair leaky cells, particularly in SRAM applications.

### SUMMARY OF INVENTION

The present invention overcomes these and other problems by providing a current source architecture that has a separate current source for each group in a block of memory. When a leaky cell is detected, a fuse between the current source and the leaky group of cells is blown and a spare group of memory is substituted for the leaky group of memory. In one embodiment, there are eight groups in a block of memory.

This current source architecture can be used in a test mode or in a current force test mode. The test mode detects if there is a leaky group of memory. In the current force test mode, the architecture determines the amount of current required by each group of memory to retain data. This information is then used to apply the required amount of current to each group of memory for data retention. As a result, the current consumed can be reduced.

### BRIEF DESCRIPTION OF THE DRAWINGS

FIG. 1 is a block diagram of a prior art memory system;

FIG. 2 is a block diagram of a memory system in accordance with one embodiment of the invention;

FIG. 3 is a circuit diagram of current source circuit in accordance with one embodiment of the invention;

FIG. 4 is a circuit diagram of a test circuit in accordance with one embodiment of the invention;

FIG. 5 is a flow chart of a method of operating a memory system in accordance with one embodiment of the invention; and

FIG. 6 is a flow chart of a method of operating a memory system in accordance with one embodiment of the invention.

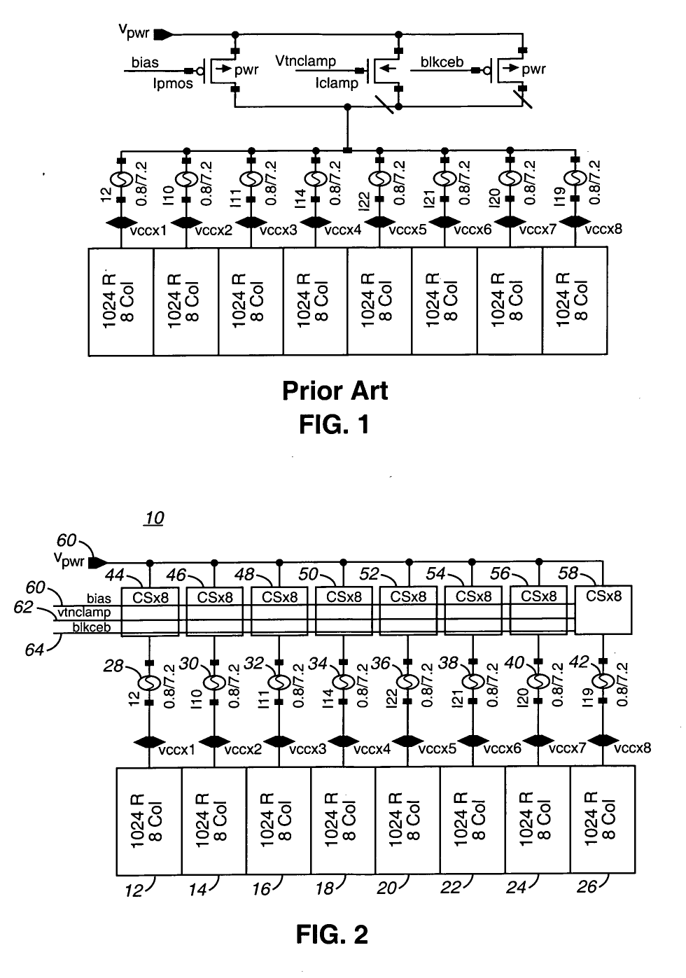

### DETAILED DESCRIPTION OF THE DRAWINGS

The present invention is directed at current source architecture that has a separate current source for each group in a block of memory. When a leaky cell is detected, a fuse between the current source and the leaky group of cells is blown and a spare group of memory is substituted for the leaky group of memory. In one embodiment, there are eight groups in a block of memory.

This current source architecture can be used in a current source test mode or in a current force test mode. The current source test mode detects if there is a leaky group of memory. In the current force test mode, the architecture determines the amount of current required by each group of memory to retain data. This information is then used to apply the required amount of current to each group of memory for data retention. As a result, the current consumed can be reduced.

FIG. 2 is a block diagram of a memory system 10 in accordance with one embodiment of the invention. The memory system has eight groups of memory 12, 14, 16, 18, 20, 22, 24, 26. Each group of memory is eight columns by 1024 rows of memory and the eight groups form a block of memory. Attached to each group of memory is a fuse 28, 30, 32, 34, 36, 38, 40, 42. The fuses connect the groups of memory to one of the current source circuits 44, 46, 48, 50, 52, 54, 56, 58. Each current source circuit has three input signals, the bias signal 60, the voltage clamp (vtnclamp) signal 62 and the active switch input (blkceb) 64. The current source circuits are coupled to a power supply (Vpwr) 60.

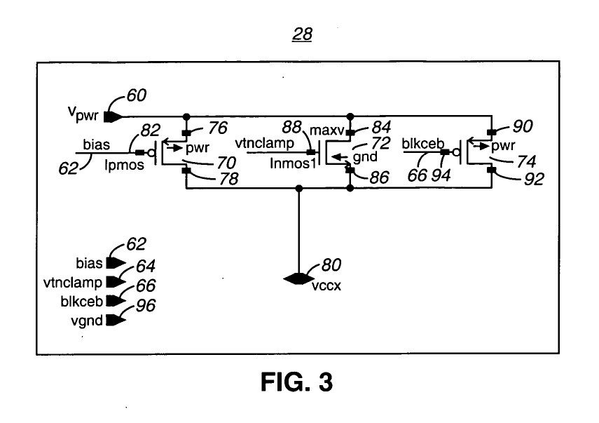

FIG. 3 is a circuit diagram of current source circuit 28 in accordance with one embodiment of the invention. Note that all the current source circuits in FIG. 2 are the same and therefore only current source circuit 28 is explained in detail. The current source circuit 28 has three transistors. The first pmos transistor 70 is the current source for a memory group. A nmos transistor 72 acts as the voltage clamp for the current source circuit 28. A second pmos transistor 74 is the active switch is used to drive huge current into the memory array when it transitions from standby to active mode. This is required for accessing the memory location faster. The source 76 of the pmos transistor 70 is coupled to the power supply voltage 60. The drain 78 is coupled to the node Vccx 80. The gate 82 is coupled to the bias signal 62. The drain 84 of the nmos transistor 72 is coupled to the power supply voltage 60. The source 86 of the nmos transistor 72 is coupled to the node Vccx 80. The gate 88 is coupled to the voltage clamp signal 64. The source 90 of pmos transistor 74 is coupled to the power supply voltage 60. The drain 92 is coupled to the node Vccx 80. The gate 94 is coupled to the active switch signal (blkceb) 66. A ground 96 is also provided to the circuit 28. The memory architecture of FIGS. 2 & 3 may be used in a current source test mode to determine which if any of the groups of memory are leaky. The current source test mode is used to detect any leaky groups of memory. To identify a leaky group of memory in this test mode, the circuit disables the voltage clamp and the active block switch. In this test mode, the chip is placed in a data retention condition and is tested for any data retention failures. When the cells in any group are more leaky, the vccx of that particular group will collapse and thus the group will not be able to hold data. This will result in data retention failures. The leaky group of memory can be identified by knowing which group of the memory failed for data retention. This group can be replaced with a spare (redundant) group of 1024 rows×8 columns. Since the current source for each one of the 8 groups in the block is separate, if any one or more cells in a group is leaky, that group will fail the data retention test and can be replaced with a spare (redundant) group of 1024 rows×8 columns by blowing the power supply (vccx) fuse for that group alone. This will enable the repair of ISB (junction leakage current and sub-threshold current) failures in addition to repairing the conventional gross functional failures in SRAMs.

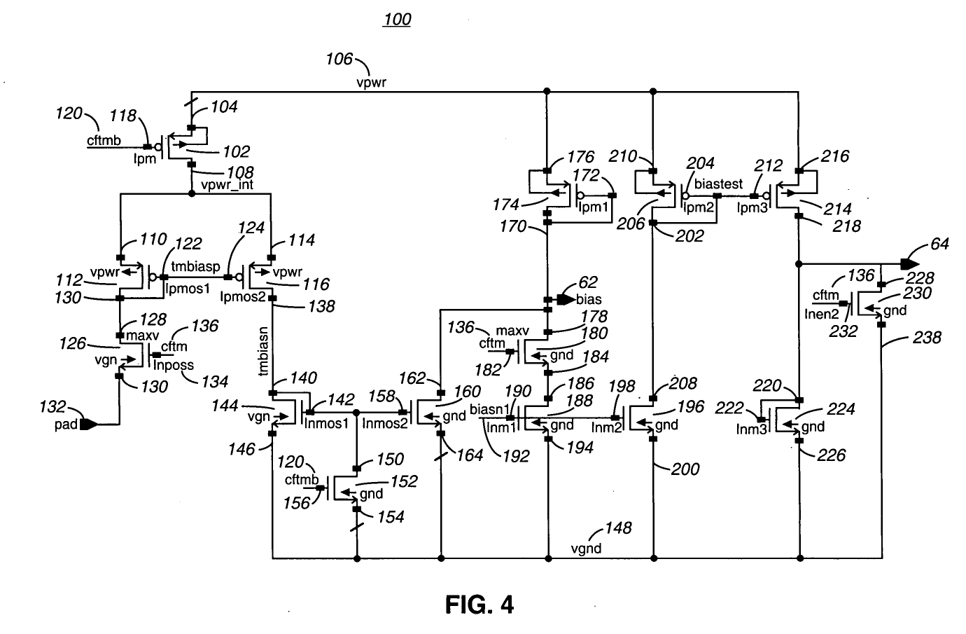

FIG. 4 is a circuit diagram of a test circuit 100 in accordance with one embodiment of the invention. The circuit 100 has a pmos transistor 102 with a source 104 coupled to the power supply voltage (Vpwr) 106. The drain 108 of transistor 102 is coupled to the source 110 of pmos transistor 112 and to the source 114 of pmos transistor 116. The gate 118 of transistor 102 is coupled to current force test control signal bar (cftmb) 120. The gate 122 of transistor 112 is coupled to the gate 124 of transistor 116. A nmos transistor 126 has its drain 128 coupled to the drain 130 and gate 122 of transistor 112. The source 130 of transistor 126 is coupled to the test pad 132. The gate 134 of transistor 126 is coupled to the current force test control signal (cftm) 136. The drain 138 of transistor 116 is coupled to the drain 140 and gate 142 of nmos transistor 144. The source 146 of transistor 144 is coupled ground 148. The gate 142 of transistor 144 is coupled to the source 150 of nmos transistor 152. The drain 154 of transistor 152 is coupled to ground 148. The gate 156 of transistor 152 is coupled to the current force test control signal (cftm) 136. The gate 142 of transistor 140 is coupled to the gate 158 of nmos transistor 160. The drain 162 of transistor 160 is coupled to the bias signal 62. The source 164 of transistor 160 is coupled to ground 148. Transistors 102, 112, 116, 126, 140, 152, 160 form the test mode circuitry.

The rest of the circuit generates the bias signal 62 and the voltage clamp signal (vtnclamp) 64. The bias node 62 is coupled to the drain 170 and gate 172 of pmos transistor 174. The source 176 of transistor 174 is coupled to the power supply 106. The bias node 62 is also coupled to the drain 178 of transistor 180. The gate 182 of transistor 180 is coupled to the current force test control signal (cftm) 136. The source 184 of transistor 180 is coupled to the drain 186 of transistor 188. The gate 190 of transistor 188 is coupled to the control signal bias1 192. The source 194 of transistor 188 is coupled to ground 148. An nmos transistor 196 has its gate 198 coupled to the control signal bias1 192. The source 200 of transistor 196 is coupled to ground 148. A drain 202 and gate 204 of pmos transistor 206 is coupled to the drain 208 of transistor 196. A source 210 of transistor 204 is coupled to the power supply 106. A gate 212 of pmos transistor 214 is coupled to the gate 204 of transistor 206. The source 216 is coupled to the power supply 106. A drain 218 is coupled to the voltage clamp node 64 and to the drain 220 and gate 222 of nmos transistor 224. The source 226 of transistor 224 is coupled to ground 148. The voltage clamp node 64 is coupled to the drain 228 of nmos transistor 230. The gate 232 of transistor 230 is coupled to the current force test control signal (cftm) 136. The source 234 of transistor 230 is coupled to ground 148.

Using the circuit of FIG. 4 in the current force test mode, the current is forced onto a test mode pad is mirrored 1/20 times into each block in the memory array. This test mode also disables the voltage clamp and the active block switch and cuts off the current path from the internal bias generator circuit. By modulating the current forced onto the pad an optimal threshold value of the current to be sourced into each block can be found out. The optimal threshold is the one which consumes minimum current and is still able to retain the data in the memory. This optimal threshold value of the current can be found for every technology in order to achieve lower standby current (ISB) for the SRAM.

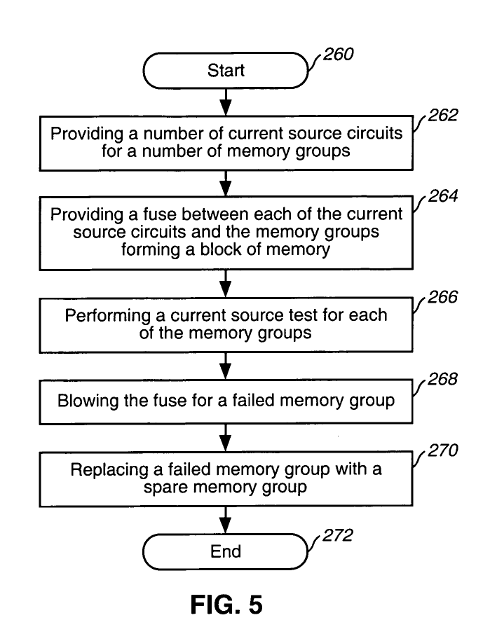

FIG. 5 is a flow chart of a method of operating a memory system in accordance with one embodiment of the invention. The process starts, step 260, by providing a number of current source circuits for a number of memory groups at step 262. At step 264, a fuse is provided between each of the current source circuits and the memory groups that form a block of memory. At step 266, a current source test for each of the memory groups is performed. This test may be performed by doing a read of the memory to determine if there were any data retention errors. At step 268 a fuse is blown for any failed memory group. At step 270, the failed memory group is replaced with a spare memory group which ends the process at step 272.

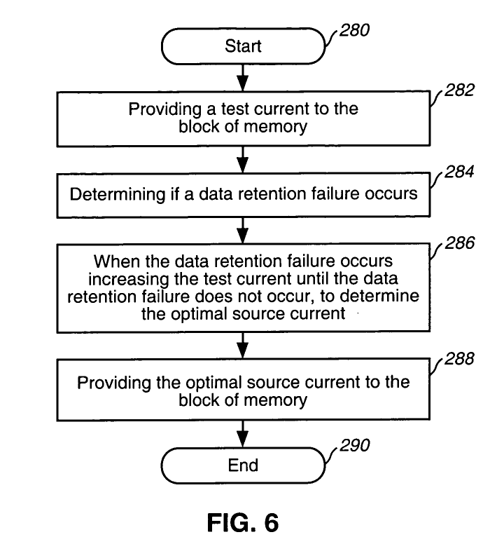

FIG. 6 is a flow chart of a method of operating a memory system in accordance with one embodiment of the invention. The process starts, step 280, by providing a test current to the block of memory at step 282. At step 284, it is determined if a data retention failure has occurred. At step 286 when a data retention failure occurs, the test current is increased until the data retention failure does not occur to determine an optimal source current. At step 288 the optimal test current is provided to the block of memory which ends the process at step 290.

Note that a block of memory is a larger grouping than a group of memory. Commonly a block of memory is eight or sixteen byte/word wide in the number of columns, while a group is one byte/word wide in the number of columns.

Thus there has been described memory system having a current source architecture that has a separate current source for each group in a block of memory. When a leaky cell is detected, a fuse between the current source and the leaky group of cells is blown and a spare group of memory is substituted for the leaky group of memory. In one embodiment, there are eight groups in a block of memory.

This current source architecture can be used in a current source test mode or in a current force test mode. The current source test mode detects if there is a leaky group of memory. In the current force test mode, the architecture determines the amount of current required by each group of memory to retain data. This information is then used to apply the required amount of current to each group of memory for data retention. As a result, the current consumed can be reduced.

While the invention has been described in conjunction with specific embodiments thereof, it is evident that many alterations, modifications, and variations will be apparent to those skilled in the art in light of the foregoing description. Accordingly, it is intended to embrace all such alterations, modifications, and variations in the appended claims.

What is claimed is:

1. A method of operating a memory system, comprising the steps of:
a) providing a plurality of current source circuits for a plurality of memory groups;
b) providing a fuse between each of the plurality of current source circuits and the plurality of memory groups forming a block of memory.

2. The method of claim 1, further including the steps of:
c) performing a current source test for each of the plurality of memory groups;
d) blowing the fuse for a failed memory group.

3. The method of claim 2, further including the step of:
e) replacing the failed memory group with a spare memory group.

4. The method of claim 2, wherein step (c) further includes the steps of:
c1) deactivating a voltage clamp transistor in the current source circuit;
c2) deactivating an active switch of the current source circuit.

5. The method of claim 4, further including the step of:
c3) determining for each of the plurality of groups of memory if a data retention failure occurs.

6. The method of claim 1 further including the steps of:
c) performing a current force test for a block of memory to determine an optimal source current;
d) providing the optimal source current to the block of memory.

7. The method of claim 6, wherein step (c) further includes the steps of:
c1) providing a test current to the block of memory;
c2) determining if a data retention failure occurs;
c3) when the data retention failure occurs increasing the test current until the data retention failure does not occur, to determine the optimal source current.

8. The method of claim 6, further including the steps of:
e) dividing the optimal source current by a number of groups of memory in the block of memory to define an optimal group source current;
f) providing the optimal group source current to each of the plurality of groups of memory.

9. A method of operating a memory system, comprising the steps of:
a) performing a current force test for a block of memory to determine an optimal source current; and
b) providing the optimal source current to the block of memory.

10. The method of claim 9, wherein step (a) further includes the steps of:
a1) providing a test current to the block of memory;
a2) determining if a data retention failure occurs;
a3) when the data retention failure occurs increasing the test current until the data retention failure does not occur, to determine the optimal source current.

11. The method of claim 9, further including the steps of:
c) providing a plurality of current source circuits for a plurality of memory groups;
d) providing a fuse between each of the plurality of current source circuits and the plurality of memory groups forming a block of memory.

12. The method of claim 11, further including the steps of:
e) dividing the optimal source current by a number of groups of memory in the block of memory to define an optimal group source current;
f) providing the optimal group source current to each of the plurality of groups of memory.

13. A method of operating a memory system, comprising the steps of:
a) providing a data retention current to each of a plurality of memory groups; and
b) providing a fuse to each of the plurality of memory groups forming a block of memory.

14. The method of claim 13, further including the steps of:
c) providing a current source circuit to provide the data retention current.

15. The method of claim 14, wherein step (c) further includes the steps of:
c1) providing a current source transistor having a source coupled to a power supply.

16. The method of claim 14, wherein step (c) further includes the steps of:
c1) providing a voltage clamp transistor having a drain coupled to a power supply.

17. The method of claim 14, wherein step (c) further includes the steps of:
c1) providing an active switch transistor having a source coupled to a power supply.

18. The method of claim 15, further including the steps of:
d) performing a current source test for each of the plurality of memory groups;
c) blowing the fuse for a failed memory group.

19. The method of claim 18, further including the step of:
e) replacing a failed memory group with a spare memory group.

20. The method of claim 13 further including the steps of:
c) performing a current force test for a block of memory to determine an optimal source current;
d) providing the optimal source current to the block of memory.
